(19) United States
(12) Patent Application Publication
(10) Pub. No.: US 2026/0141129 A1
(43) Pub. Date: May 21, 2026

(54) SYSTEMS AND METHODS FOR GENERATING AN OBJECT DESIGN USING A MODEL WITH MULTI-MODAL INPUTS

(71) Applicant: Toyota Research Institute, Inc., Los Altos, CA (US)

(72) Inventors: Rui Zhou, Cambridge, MA (US); Yanxia Zhang, Foster City, CA (US); Chenyang Yuan, Cambridge, MA (US); Frank Noble Permenter, Cambridge, MA (US); Nikos Arechiga Gonzalez, San Mateo, CA (US); Matthew Evans Klenk, San Francisco, CA (US); Faez Ahmed, Winchester, MA (US)

(73) Assignees: Toyota Research Institute, Inc., Los Altos, CA (US); Toyota Jidosha Kabushiki Kaisha, Toyota-shi Aichi-ken (JP); Massachusetts Institute of Technology, Cambridge, MA (US)

(21) Appl. No.: 19/063,802

(22) Filed: Feb. 26, 2025

Related U.S. Application Data
(60) Provisional application No. 63/720,946, filed on Nov. 15, 2024.

(51) Int. Cl. G06F 30/10; G06F 40/30

(52) U.S. Cl. CPC G06F 30/10; G06F 40/30

(57) ABSTRACT

Systems, methods, and other embodiments described herein relate to controlling a model using data fusion and a multi-modal conditional embedding for generating an object design. In one embodiment, a method includes constructing a completed parameter and an assembled component using completion models from an assembly graph, an incomplete parameter, and a component image about an object design. The method also includes generating input embeddings using encoding models associated with the completed parameter, the assembled component, and a text description. The method also includes computing a multi-modal conditional embedding using multi-modal fusion from the input embeddings. The method also includes controlling a foundational model using the multi-modal conditional embedding with a controlnet and outputting a generated object.

### CROSS-REFERENCE TO RELATED APPLICATIONS

This application claims the benefit of U.S. Provisional Application No. 63/720,946, filed on Nov. 15, 2024, which is herein incorporated by reference in its entirety.

### TECHNICAL FIELD

The subject matter described herein relates, in general, to generating an object design, and, more particularly, controlling a model using a multi-modal conditional embedding for generating the object design.

### BACKGROUND

Systems for engineering design can involve the creation, analysis, and optimization of products and processes to meet technical specifications. These systems can rely upon operator expertise, creativity, and problem-solving skills to navigate a vast design space and identify optimal solutions. The advancement of artificial intelligence (AI) creates opportunities to enhance engineering designs. For example, a model learns to generate new data points according to patterns in training data. In this way, the model can extrapolate and form creative designs that involve optimization and automation.

In various implementations, systems implement deep learning and probabilistic models for inspiring engineering designs through exploring design alternatives. Furthermore, these systems can uncover unexpected concepts and streamline design workflows. However, applications in engineering design using deep learning encounter challenges. For instance, the models have difficulties understanding nuisances in a control parameter that is critical to engineering and architectural qualities about an object. Therefore, systems using learning models for engineering designs can lack capabilities for identifying comprehensive objects.

### SUMMARY

In one embodiment, example systems and methods relate to controlling a model using data fusion and a multi-modal conditional embedding for generating an object design. In various implementations, systems implement a generative model for filling gaps between machine learning (ML) and engineering design through outputting creative objects from inputted parameters. The generative model can automatically create, optimize, and evaluate a design during engineering. However, these systems sometimes lack capabilities such as allowing precise control over generated content. Another constraint is a generative model having difficulties in understanding performance metrics and physical properties. Furthermore, generative models can be unable to handle diverse tasks for complex engineering designs. For example, a diffusion-based model (e.g., stable diffusion) generates a realistic image from textual descriptions but computations have limits with accurately following parametric inputs, assembly constraints, etc., associated with the engineering process. Therefore, systems using a generative model for assisting with a design task during an engineering and architectural process can have deficiencies.

Therefore, in one embodiment, a generation system controls design with parametric, component image, and text modalities that enhance generative precision and diversity. The parametric modalities can be incomplete, partial, and complete parametric inputs that a diffusion model automatically completes and a parametric encoder computes an embedding that streamlines processing. In one approach, the generation system utilizes an assembly graph to systematically assemble an inputted component image. A component encoder can process the component image to capture visual data from the assembly graph that is key. Furthermore, a data-driven encoder forms a text embedding from the text that describes a target design, thereby ensuring a comprehensive interpretation of design intent.

In various implementations, the generation system synthesizes the various embeddings outputted by encoders with a multi-modal fusion model. For example, the multi-modal fusion model creates a joint embedding for an input to a control model that precisely and accurately conforms with design parameters. This integration allows the generation system to apply robust multi-modal control to foundation models that facilitate tasks demanding complex, diverse, and precise execution (e.g., engineering, architecture, etc.). Accordingly, the generation system expands the capabilities of intelligent design tools through precise control of models using diverse data modalities for superior design generation.

In one embodiment, a generation system for controlling a model using data fusion and a multi-modal conditional embedding for generating an object design is disclosed. The generation system includes a memory having instructions that, when executed by a processor, cause the processor to construct a completed parameter and an assembled component using completion models from an assembly graph, an incomplete parameter, and a component image about an object design. The instructions also include instructions to generate input embeddings using encoding models associated with the completed parameter, the assembled component, and a text description. The instructions also include instructions to compute a multi-modal conditional embedding using multi-modal fusion from the input embeddings. The instructions also include instructions to control a foundational model using the multi-modal conditional embedding with a controlnet and output a generated object.

In one embodiment, a non-transitory computer-readable medium for controlling a model using data fusion and a multi-modal conditional embedding for generating an object design and including instructions that when executed by a processor cause the processor to perform one or more functions is disclosed. The instructions include instructions to construct a completed parameter and an assembled component using completion models from an assembly graph, an incomplete parameter, and a component image about an object design. The instructions also include instructions to generate input embeddings using encoding models associated with the completed parameter, the assembled component, and a text description. The instructions also include instructions to compute a multi-modal conditional embedding using multi-modal fusion from the input embeddings. The instructions also include instructions to control a foundational model using the multi-modal conditional embedding with a controlnet and output a generated object.

In one embodiment, a method for controlling a model using data fusion and a multi-modal conditional embedding for generating an object design is disclosed. In one embodiment, the method includes constructing a completed parameter and an assembled component using completion models from an assembly graph, an incomplete parameter, and a component image about an object design. The method also includes generating input embeddings using encoding models associated with the completed parameter, the assembled component, and a text description. The method also includes computing a multi-modal conditional embedding using multi-modal fusion from the input embeddings. The method also includes controlling a foundational model using the multi-modal conditional embedding with a controlnet and outputting a generated object.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one embodiment of a generation system that is associated with controlling a model using data fusion and a multi-modal conditional embedding for generating an object design.

FIG. 2 illustrates one embodiment of a pipeline using the generation system of FIG. 1 that fuses multi-modal inputs for controlling a model during a design task.

FIG. 3 illustrates an example of the generation system designing various objects using different text prompts.

FIG. 4 illustrates one embodiment of a method that is associated with controlling a foundational model using a multi-modal conditional embedding with a control model and outputting a generated object.

### DETAILED DESCRIPTION

Systems, methods, and other embodiments associated with controlling a model using data fusion and a multi-modal conditional embedding for generating an object design are disclosed herein. In various implementations, systems use generative models that are pre-trained to synthesize and optimize various design tasks. For example, a diffusion model learns to generate samples by reversing a gradual noising process. This can include starting from random noise and iteratively denoising until identifying a clean and refined sample associated with a task. Still, generative and diffusion models executing design tasks face challenges involving precise control over generation and customized outputs sought by specialized applications. For instance, a model is incapable of allowing an engineer to adjust size and texture without altering the overall structure of an image.

Moreover, although pre-trained models (e.g., foundation models) can generate novel and realistic-looking images, these models sometimes lack the capabilities to generate functional designs that obey parametric and assembly constraints associated with product engineering (e.g., vehicle assembly). Training models is difficult with deficiencies in acquiring labeled and cleaned datasets that are vast. Furthermore, generative models can be limited to certain input types and quantities that can increase engineering time. As such, systems using current models lack capabilities for nuanced control over a design task and lack training data for customizing models.

Therefore, in one embodiment, a generation system combines a diffusion model with multi-modal fusion and control that facilitates versatile and effective generative tasks for engineering design. In particular, the generation system can capture both design intent and engineering constraints while generating optimized designs that satisfy specified requirements through diverse inputs including parametric data, an assembly graph, a component image, and a textual description. As such, the generation system exhibits precise multi-modal control over a foundation model (e.g., text-to-image (T2I)) allowing the design of conditioned new types of information. Furthermore, the generation system derives embeddings for different input types that improve pipeline processing. In this regard, the generation system can complete and embed partial parameters using diffusion and encoding models. As other input processing, a component encoder generates a component embedding for an inputted component image factoring the assembly graph while a text encoder forms text embedding from the text description.

In various implementations, a multi-modal fusion model receives the parametric embedding, the component embedding, and the text embedding to derive a multi-modal conditional embedding. In one approach, this allows a control model (e.g., a controlnet) to direct a model layer-by-layer using the multi-modal conditional embedding. As such, the generation system can output designs that closely adhere to input parametric specifications, assembly boundaries, and creative prompts while maintaining superior visual quality and diversity. For instance, multi-modal control with the control model within automotive engineering allows concurrent adjustments to the aerodynamics and aesthetics of a target vehicle using performance simulations and design criteria. This ensures that the final product meets both functional and visual standards. Accordingly, the generation system has enhanced capabilities to handle complex engineering and design tasks that include generating designs with specific functional requirements and spatial constraints.

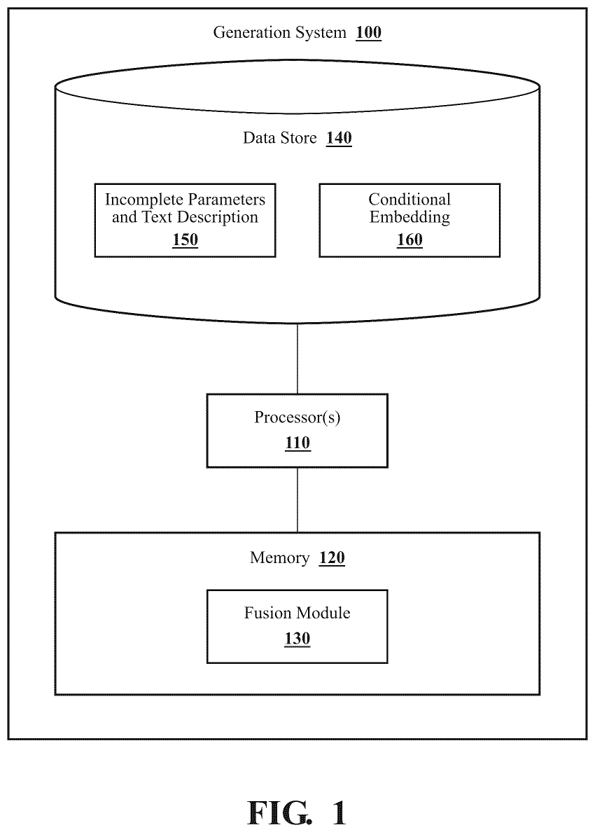

Referring to FIG. 1, one embodiment of a generation system 100 that is associated with controlling a model using data fusion and a multi-modal conditional embedding for generating an object design is illustrated. The generation system 100 also includes various elements. It will be understood that in various embodiments, the generation system 100 may have less than the elements shown in FIG. 1. The generation system 100 can have any combination of the various elements shown in FIG. 1. Furthermore, the generation system 100 can have additional elements to those shown in FIG. 1. In some arrangements, the generation system 100 may be implemented without one or more of the elements shown in FIG. 1. Furthermore, the elements shown may be physically separated by large distances.

It will be appreciated that for simplicity and clarity of illustration, where appropriate, reference numerals have been repeated among the different figures to indicate corresponding or analogous elements. In addition, the discussion outlines numerous specific details to provide a thorough understanding of the embodiments described herein. Those of skill in the art, however, will understand that the embodiments described herein may be practiced using various combinations of these elements. In either case, the generation system 100 includes a fusion module 130 that is implemented to perform methods and other functions as disclosed herein relating to controlling a model using data fusion and a multi-modal conditional embedding for generating an object design.

In one embodiment, the generation system 100 includes a memory 120 that stores the fusion module 130. The memory 120 is a random-access memory (RAM), a read-only memory (ROM), a hard-disk drive, a flash memory, or other suitable memory for storing the fusion module 130. The fusion module 130 is, for example, computer-readable instructions that when executed by the processor(s) 110 cause the processor(s) 110 to perform the various functions disclosed herein.

In various implementations, the generation system 100 and the fusion module 130 generally include instructions that function to control the processor(s) 110. In one embodiment, the generation system 100 includes a data store 140. In one embodiment, the data store 140 is a database. The database is, in one embodiment, an electronic data structure stored in the memory 120 or another data store and that is configured with routines that can be executed by the processor(s) 110 for analyzing stored data, providing stored data, organizing stored data, and so on. Thus, in one embodiment, the data store 140 stores data used by the fusion module 130 in executing various functions. In one embodiment, the data store 140 includes incomplete parameters and a text description 150 and a conditional embedding 160. An incomplete parameter may be a measurement, data, etc., that leaves inference space and estimating tasks for the generation system 100 to complete the parameter. For example, a table specifies a saddle height without a tube length involving a bike design task. The generation system 100 completes the tube length in the table as described below. A text description can specify design qualities, categories, classes, etc., about a design. For instance, a text description for an input is a road bike.

Moreover, as further explained below, the conditional embedding 160 can capture and represent relationships between different modalities such as images and text. Here, embeddings can be numerical representations of real-world objects that the generation system 100 uses to understand complex and diverse knowledge domains that mimic a human. Conditioning a generative process can also include inputs such as relating edge maps for architecture, human pose graphs for specific motion generation, etc., as embeddings that control a downstream model, a foundational model, etc. In this way, the generation system 100 can precisely control complex tasks for a generative model during an engineering design.

The generation system 100 and the fusion module 130, in one embodiment, is further configured to perform additional tasks having instructions that cause the processor 110 to construct a completed parameter and an assembled component using completion models from an assembly graph, an incomplete parameter, and a component image about an object design. The generation system 100 can generate input embeddings using encoding models associated with the completed parameter, the assembled component, and a text description. The fusion module 130 can compute a multi-modal conditional embedding using multi-modal fusion from the input embeddings. Furthermore, the generation system 100 can control a foundational model using the multi-modal conditional embedding with a controlnet and output a generated object accordingly. In this way, the generation system 100 expands the capabilities of design tools (e.g., engineering tools) through precise control involving generative models using diverse data modalities that improve performance and increase design capabilities.

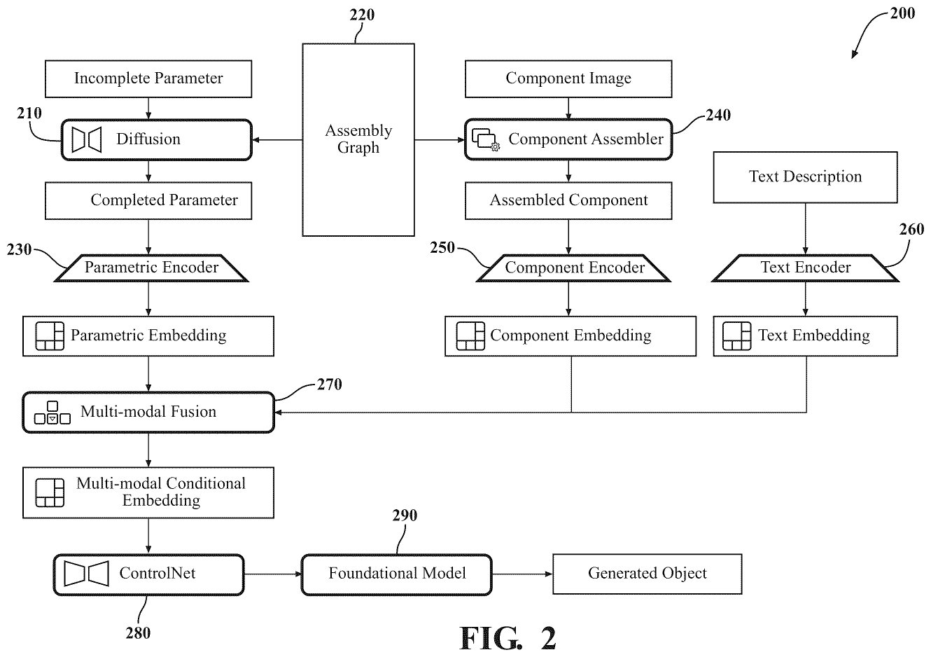

Concerning FIG. 2, one embodiment of a pipeline 200 using the generation system 100 of FIG. 1 that fuses multi-modal inputs for controlling a model during a design task is illustrated. Here, a diffusion model 210 can be a completion model that constructs the completed parameter by estimations from an incomplete parameter and an assembly graph 220. In this regard, the assembly graph 220 identifies relationships between components (e.g., vehicle components, product components, etc.) of the object design (e.g., a vehicle). For instance, the assembly graph 220 relates components and features about an object design in a manner that reduces computations and improves accuracy when completing the incomplete parameters.

The assembly graph 220 also can have edges connecting nodes that are structurally related. An edge exists between nodes when corresponding components are physically coupled, interact, etc., within a structure (e.g., a vehicle, a product, etc.). As such, the edges can indicate relations between components using weights. The relationships can be expert-driven when forming the input to the generation system 100 and the pipeline 200.

In one approach, the diffusion model 210 imputes parametric interdependencies from the assembly graph 220 about an object design using a graph attention network (GAN) and utilizes a tabular model approach that is pre-trained. Here, the diffusion model 210 can generate diverse and complete parametric designs for incomplete parameters. In one approach, the pipeline 200 bypasses the diffusion model 210 when given a completed parameter for a design. In another approach, the diffusion model 210 feeds a parametric encoder 230 that computes parametric embeddings. For example, the parametric encoder 230 is a network with fully connected layers (e.g., two) that derives a compact parametric embedding. A fully connected approach has at least one layer in a neural network where every neuron in one layer is connected to every neuron in the next layer. As previously explained, embeddings can be numerical representations of real-world objects that the pipeline 200 can use to understand complex knowledge domains similar to a human, thereby improving generation performance and accuracy. Thus, the diffusion model 210 can improve the flexibility and adaptability of the pipeline 200 through autocompletion that allows a foundational, generative, etc., model to handle incomplete parametric information effectively and output design recommendations from available parametric data.

Regarding component assembly and encoding, the component assembler 240 outputs an assembled component from an inputted component image and the assembly graph 220 about an object design. As explained below, the component assembler 240 can scale and position a design image for the object design according to the assembly graph 220. The assembly graph 220 can identify relationships between the component image (e.g., a wheel, a door, a window, etc.) of the object design using edges and nodes. Furthermore, a size and a position of the component image can be defined and associated with the assembly graph 220. As such, the generation system 100 can estimate the assembled component using the component assembler 240 as a completion model from the component image and the assembly graph 220 as inputs. This can include extracting a feature and a pattern from the assembled component using the component encoder 250 (e.g., a convolutional network) and computing a component embedding using the component encoder 250 from the feature and the pattern.

The component assembler 240 can also utilize the structural information provided by the assembly graph 220 to assemble inspirations from a component image into a coherent representation. Here, a node in the assembly graph 220 may represent a component and an edge defines connections, relative positions, and relative sizes between one or more components. In one approach, the component assembler 240 implements assembly Algorithm 1 that retrieves corresponding component inspirations from component images. The Algorithm 1 can position and scale the images according to size and position attributes specified in the assembly graph 220. Furthermore, the pipeline 200 and the generation system 100 can layer correctly-sized component images for generating and outputting a composite image as an assembled component representing an assembled design.

Algorithm 1 Component Assembly Algorithm

| Require: Assembly graph G = (V, E), component im- | |
|---|---|
| ages {Iᵥ: v ∈ V}, size and position attributes | |
| {(sᵥ, pᵥ) : v ∈ V} | |
| Ensure: Assembled composite image I_{comp} | |
| 1: | Initialize a blank canvas I_{comp} |
| 2: | for each node v ∈ V do |
| 3: | Resize component image Iᵥ to the specified size |
| sᵥ | |
| 4: | Place resized Iᵥ at the position pᵥ on the canvas |
| 5: | Overlay Iᵥ on I_{comp} |

```
  end for
  return I_{comp}
```

In another approach, the generation system 100 implements Algorithm 1 to have a component image Iᵥ adjusted according to the size attribute sᵥ specified in the assembly graph 220. Positioning pᵥ determines a canvas location of Iᵥ. In another example, the generation system 100 layers sequentially resized and positioned component images to create a composite image I_{comp} that represents the assembled design.

Regarding component encoding, the component encoder 250 computes and outputs a component embedding, such as through feature extraction. As previously explained, embeddings can be numerical representations of real-world objects that the pipeline 200 can use to understand knowledge domains that are complex and replicate human understanding, thereby increasing generation performance and accuracy. In one approach, the component encoder 250 is a convolution network having multiple layers (e.g., 4, 8, etc.) that identify and extract salient information from the assembled component. In another example, an assembled composite image is encoded into a meaningful representation using the component encoder 250 consisting of convolutional and linear layers. For instance, the component encoder 250 comprises 8 convolutional layers with the following configuration: 2 layers with a dimension of 16 and filter size 3, 2 layers with a dimension of 32 and filter size 3, 2 layers with a dimension of 96 and filter size 3, 1 layer with a dimension of 256 and filter size 3, and 1 final layer with a dimension of 319. Although examples here are given for certain layers, dimensions, and filter sizes, a person of ordinary skill in the art will understand that different numbers and quantities can be implemented for feature extraction.

In various implementations, convolutional layers within the component encoder 250 extract relevant features and patterns from the component image. This allows capturing the spatial and structural information of the assembled design. In particular, the form of the component encoder 250 allows task-specific feature extraction and capturing detailed spatial relationships by the generation system 100 for engineering design.

The pipeline 200 also includes text encoder 260 that computes and outputs a text embedding from the text description (e.g., race car, speed bike, etc.) about an object design. In an example, the text encoder 260 implements one of a contrastive language-image pre-training (CLIP) model, a transformer model, a stable diffusion model, a pre-trained data-driven model, and an embedding layer and projects outputs into a subspace of X dimensions (e.g., 4096). This allows the generation system 100 and the pipeline 200 to capture and derive semantic information and design intent.

Regarding additional embodiments, the pipeline 200 can incorporate and expand additional control modalities for specific design and engineering tasks. For instance, one of a mesh cloud, a point cloud, etc., can be an input associated with an image, schematic, etc., of a design task. Such information can improve conditioning and control of a generative model associated with the design task including engineering performance (e.g., dynamics, ergonomics, structural, aerodynamics, etc.), environmental factors (design for specific terrains), etc., through factoring two-dimensional (2D) and three-dimensional (3D) information.

In another example, the pipeline 200 feeds tables, vectors, etc., representing input embeddings and outputted from the parametric encoder 230 (e.g., a pre-trained network), the component encoder 250, and the text encoder 260 to the multi-modal fusion model 270. This operation synthesizes diverse data modalities including engineering parametric data, component assembly, and textual descriptions into a unified design representation. As further explained below, outputs from the multi-modal fusion model 270 include multi-modal conditional embedding that can be derived by concatenating a parametric embedding from the input embeddings associated with the completed parameter with a component embedding from the input embeddings associated with the assembled component. Furthermore, the multi-model conditional embedding can involve projecting the parametric embedding and the component embedding into a multi-dimensional vector, and adding the parametric embedding and the component embedding to a text embedding from the input embeddings that in all represents design intent.

As additional details, the pipeline 200 and the generation system 100 can concatenate the parametric embedding and the component embedding and project the result into a vector using a fully connected layer. In one approach, the vector can then be added to a CLIP embedding from diffusion (e.g., stable diffusion, a pre-trained diffusion model, a pre-trained CLIP model, etc.) and outputted by the multi-modal fusion model 270. In this way, the multi-modal fusion model 270 creates a multi-modal representation that is integrated with rich data sources and exhibits contextual accuracy with an object design.

In FIG. 2, the output of the multi-modal fusion model can effect and condition operation of the control network (controlnet) 280 allowing precise control of a model (e.g., a generative model) using diverse data modalities, thereby improving engineering design. Although this example references a controlnet, the generation system 100 and the pipeline 200 can implement any network that integrates external control signals and the conditional embedding 160 for improving adaptability and precision involving a learning model downstream. In one approach, the model is a foundational model 290 (e.g., a learning model, a learning network, a large language model, Dall-e, stable diffusion, etc.) already pre-trained. The generation system 100 controlling the foundational model 290 includes modifying a vector including the multi-modal conditional embedding from the conditional embedding 160 using the controlnet 280. The controlnet 280 can then direct and control the foundational model 290 layer-by-layer using the vector that produces highly intricate objects for engineering design according to inputs.

In other respects, the controlnet 280 can act as a modifier over the foundation model 290 using the multi-modal conditional embedding. For example, the controlnet 280 guides outputs of the foundation model 290 layer-by-layer. This allows fine-grained control over a generated object according to the incomplete parameters, the component image, and the text description that are inputted.

In another embodiment, the controlnet 280 conditionally controls a diffusion model as the foundational model 290 that is pre-trained and allows designers to modify specific attributes of the generated object. In particular, the controlnet 280 facilitates creating multiple copies of diffusion layers within a network associated with the foundational model 290. A first layer can be locked while a second layer is trainable and conditioned on another input modality (e.g., images). In this example, the trainable copy of the network contains zero convolution and the results of the two networks are combined for each layer. In this way, the generation system 100 and the pipeline 200 allow computationally efficient training and robustness to overfitting as the weights of the diffusion model are locked.

Moreover, the generation system 100 and the pipeline 200 utilizing a multi-modal conditional embedding for the controlnet 280 to finely direct the foundational model 290 that is pre-trained allows conditioning a generative design with inputs including edge maps for architecture, human pose graph for a specific motion generation, etc. This approach also avoids vast amounts of data for training the foundational model 290. Furthermore, the multi-modal inputs improve capabilities for engineering design that involves a wide range of modalities including parametric data, geometric constraints, assembly instructions, and performance requirements.

Regarding training the pipeline 200, the generation system 100 can train layers of the multi-modal fusion model 270 end-to-end. Here, a learning model training end-to-end can involve learning a model parameter concurrently from input to output. As such, the learning model optimizes operation as a whole. This training approach also ensures that the multi-modal conditional embeddings are aligned and optimized for an overall generative task. In another approach, training involves having an imputation part of the pipeline 200 associated with end-to-end training pre-trained. In other words, the generation system 100 can use an imputation model as a pre-trained model to compute an embedding from tabular data while remaining parts of the pipeline 200 are trained end-to-end.

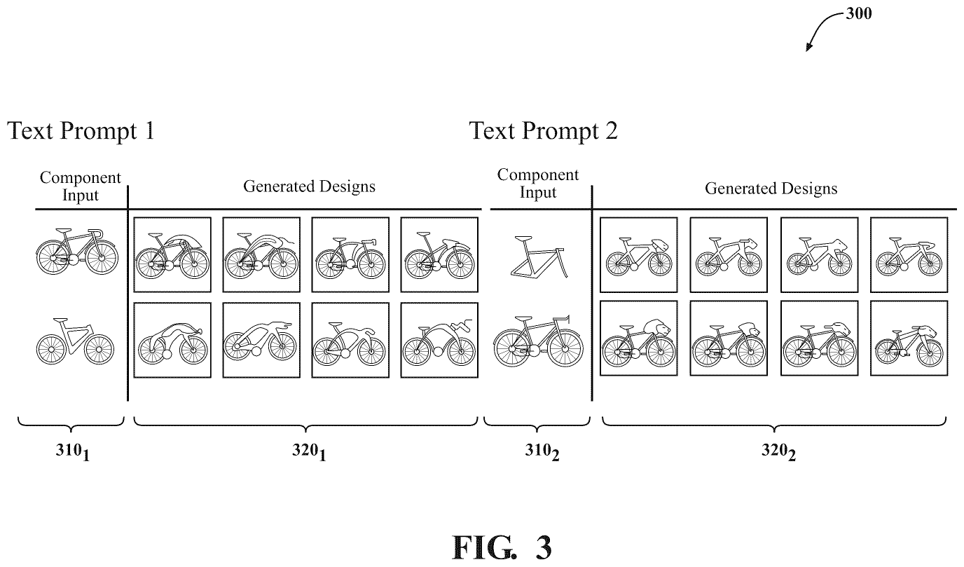

Turning to FIG. 3, an example of the generation system 100 designing various objects using different text prompts is illustrated. Here, the pipeline 200 receives a text prompt 1 (e.g., an insect looking bike) and component images 3101 as inputs that can be one of unique, complementary, and non-overlapping. Using an assembly graph, the generation system 100 and the pipeline 200 output diverse designs with the images 3201. Similarly, the pipeline 200 receives a text prompt 2 (e.g., an animal-looking bike) and component images 3102 as inputs and outputs the images 3202. Although these examples illustrate design bikes, a person of ordinary skill of the art understands that the pipeline 200 can generate and design any engineering component, object, etc. Furthermore, FIG. 3 demonstrates that the generation system 100 and the pipeline 200 can handle engineering-specific tasks by strictly adhering to detailed input parameters and complex component relationships. A modality can also independently contribute specific information that when combined forms a complete set of design specifications. The approach also integrates assembly information into the output, thereby improving design capabilities and robustness.

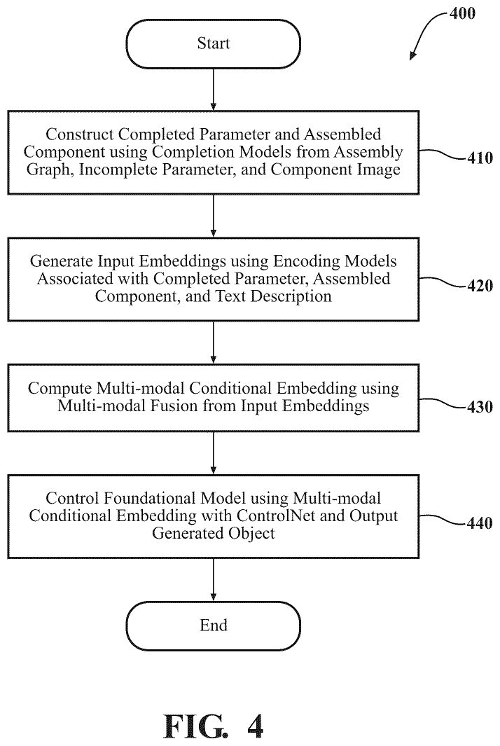

Turning to FIG. 4, one embodiment of a method 400 that is associated with controlling a foundational model using a multi-modal conditional embedding with a control model and outputting a generated object is illustrated. The method 400 will be discussed from the perspective of the generation system 100 of FIG. 1. While the method 400 is discussed in combination with the generation system 100, it should be appreciated that the method 400 is not limited to being implemented within the generation system 100 but is instead one example of a system that may implement the method 400.

The method 400 can be associated with a generative model designed to exert multi-modal control over text-to-image (T2I) foundation models specifically tailored for engineering design, engineering applications, engineering tools, product development, etc. The generation system 100 can offer precise and customized design generation by integrating diverse modalities that includes a parametric input, an assembly graph, and a component image as inspiration and allowing precise control. This enhances the fidelity and accuracy of generated designs, ensuring alignment with specifications and constraints that are invaluable in product design, architecture, and manufacturing. Furthermore, the generation system 100 facilitates the exploration of complex design spaces, thereby outputting innovative and optimized objects. The generation system 100 also gives opportunities for collaborative design by allowing diverse inputs from multi-disciplinary sources, thereby leveraging broad diverse expertise and insights.

The generation system 100 and the method 400 also give capabilities to iteratively refine and explore design alternatives in a collaborative environment through incorporating feedback from stakeholders and domain experts. This versatility allows integration into existing design workflows and platforms that enhance productivity, streamlining, and robustness associated with a design task. For example, the generation system 100 is applied to parametric computer-aided design (CAD) problems within automotive engineering, aerospace, biomedical device, etc., domains.

At 410, the generation system 100 constructs a completed parameter and an assembled component using completion models from an assembly graph, an incomplete parameter, and a component image. The assembly graph can include edges connecting nodes that are structurally related. For instance, an edge exists between nodes when corresponding components are physically coupled, interact, etc., within a structure (e.g., a vehicle, a product, etc.). Here, the edges can indicate intricate relations between components using weights. Regarding an incomplete parameter, this can represent a measurement, data, etc., that leaves estimation tasks for the generation system 100. The component image can be a structural component (e.g., a wheel, a door, a window, etc.), a functional component (e.g., an actuator, a controller, etc.), etc., associated with an object design.

Moreover, in one embodiment, a completion model implements a diffusion model that constructs the completed parameter through estimations from an incomplete parameter and the assembly graph. As previously explained, the diffusion model can impute parametric interdependencies from the assembly graph about an object design using a GAN. In this way, the diffusion model generates diverse and complete parametric designs for incomplete parameters. Furthermore, the component assembler outputs an assembled component from an inputted component image and the assembly graph about an object design.

At 420, the generation system 100 generates input embeddings using encoding models associated with the completed parameters, the assembled component, and the text description. An embedding can be numerical representations of real-world objects that the generation system 100 leverages and utilizes to understand complex and diverse knowledge domains for replicating and mimicking human comprehension. In one approach, a parametric encoder computes parametric embeddings from the completed parameters that are derived from the incomplete parameters. As previously described, component assembly can involve extracting a feature and a pattern from the assembled component using a component encoder (e.g., a convolutional network) and computing a component embedding using the component encoder from the feature and the pattern.

Moreover, the generation system can also include a text encoder that derives and outputs a text embedding from the text description (e.g., race car, speed bike, etc.) about an object design. In an example, the text encoder implements one of a CLIP model, a transformer model, a stable diffusion model, a pre-trained data-driven model, and an embedding layer and projects outputs into a subspace. In this way, the generation system 100 can synthesize the various embeddings outputted by encoders efficiently and effectively with a multi-modal fusion model.

At 430, the generation system 100 and/or fusion module 130 compute a multi-modal conditional embedding using the multi-modal fusion model from the input embeddings. For instance, the generation system 100 feeds tables, vectors, etc., representing input embeddings and outputted from the parametric encoder, the component encoder, and the text encoder to the multi-modal fusion model. In this way, the generation system 100 manipulates and synthesizes diverse data modalities including engineering parametric data, component assembly, and textual descriptions into a unified representation associated with an object design.

Multi-modal data fusion, in one embodiment, can involve the multi-modal fusion model outputting a multi-modal conditional embedding derived from the various input embeddings. For instance, the multi-modal fusion model concatenates a parametric embedding associated with the completed parameter with a component embedding associated with the assembled component. This can also involve projecting the parametric embedding and the component embedding into a multi-dimensional vector and adding the parametric embedding and the component embedding to a text embedding from the input embeddings.

At 440, the generation system 100 controls a foundational model using the multi-modal conditional embedding with a controlnet and outputs a generated object. Here, the foundational model can be one of a learning model, a learning network, a large language model, Dall-e, stable diffusion, etc. involved with designing and generating objects. Although this example references a controlnet, the generation system 100 can implement any network that integrates external control signals and the conditional embedding 160 for improving adaptability and precision when directing, guiding, etc., a learning model. In one approach, the generation system 100 controlling the foundational model includes modifying a vector including the multi-modal conditional embedding from the conditional embedding 160. The controlnet can then control the foundational model layer-by-layer using the vector that produces highly intricate objects for engineering design according to inputs.

In one regard, the controlnet is a modifier over the foundation model using the multi-modal conditional embedding as steering. As previously described, this allows fine-grained control over the generated object according to the incomplete parameters, component image, and the text description that are inputted. Furthermore, the controlnet can conditionally control a diffusion model as the foundational model in a manner that allows designers and engineers to modify specific attributes associated with the generated object. In this way, the generation system 100 adapts with specific domain demands and constraints that unlock new opportunities for innovation and problem-solving.

Detailed embodiments are disclosed herein. However, it is to be understood that the disclosed embodiments are intended as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Furthermore, the terms and phrases used herein are not intended to be limiting but rather to provide an understandable description of possible implementations. Various embodiments are shown in FIGS. 1-4, but the embodiments are not limited to the illustrated structure or application.

The flowcharts and block diagrams in the figures illustrate the architecture, functionality, and operation of possible implementations of systems, methods, and computer program products according to various embodiments. In this regard, a block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components, and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein.

The systems, components, and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a ROM, an EPROM or flash memory, a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain, or store a program for use by or in connection with an instruction execution system, apparatus, or device.

Generally, modules as used herein include routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an ASIC, a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, radio frequency (RF), etc., or any suitable combination of the foregoing. Computer program code for carrying out operations for aspects of the present arrangements may be written in any combination of one or more programming languages, including an object-oriented programming language such as Java™, Smalltalk™, C++, or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all combinations of one or more of the associated listed items. As an example, the phrase “at least one of A, B, and C” includes A, B, C, or any combination thereof (e.g., AB, AC, BC, or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. A generation system comprising:
a memory storing instructions that, when executed by a processor, cause the processor to:
construct a completed parameter and an assembled component using completion models from an assembly graph, an incomplete parameter, and a component image about an object design;
generate input embeddings using encoding models associated with the completed parameter, the assembled component, and a text description;
compute a multi-modal conditional embedding using multi-modal fusion from the input embeddings; and
control a foundational model using the multi-modal conditional embedding with a controlnet and output a generated object.

2. The generation system of claim 1, wherein the instructions to compute the multi-modal conditional embedding further include instructions to:
concatenate a parametric embedding from the input embeddings associated with the completed parameter with a component embedding from the input embeddings associated with the assembled component;
project the parametric embedding and the component embedding into a multi-dimensional vector; and
add the parametric embedding and the component embedding to a text embedding from the input embeddings.

3. The generation system of claim 1, wherein the instructions to control the foundational model further include instructions to:
modify a vector including the multi-modal conditional embedding using the controlnet; and
control the foundational model layer-by-layer using the vector.

4. The generation system of claim 1, wherein the instructions to construct the completed parameter further include instructions to:
estimate the completed parameter using a diffusion model as one of the completion models from the incomplete parameter and the assembly graph, and the assembly graph identifies relationships between components of the object design.

5. The generation system of claim 4, wherein the instructions to estimate the completed parameter further include instructions to:
impute parametric interdependencies from the assembly graph about the object design using a graph attention network (GAN), and the diffusion model is a tabular model.

6. The generation system of claim 1, wherein the instructions to construct the completed parameter and the assembled component further include instructions to:
scale and position a design image for the object design according to the assembly graph, and the assembly graph identifies relationships between the component image of the object design using edges and nodes and a size and a position of the component image are defined by the assembly graph; and
estimate the assembled component using a component assembler as one of the completion models from the component image and the assembly graph.

7. The generation system of claim 1 further including instructions to:
extract a feature and a pattern from the assembled component using a component encoder, and the component encoder is a convolutional network; and
compute a component embedding using the component encoder from the feature and the pattern.

8. The generation system of claim 1, wherein instructions to generate the input embeddings further include instructions to:
derive semantic information and a design intent using a generative model from the text description, and the generative model is associated with one of a contrastive language-image pre-training (CLIP) model and a stable diffusion model.

9. A non-transitory computer-readable medium comprising:
instructions that when executed by a processor cause the processor to:
construct a completed parameter and an assembled component using completion models from an assembly graph, an incomplete parameter, and a component image about an object design;
generate input embeddings using encoding models associated with the completed parameter, the assembled component, and a text description;
compute a multi-modal conditional embedding using multi-modal fusion from the input embeddings; and
control a foundational model using the multi-modal conditional embedding with a controlnet and output a generated object.

10. The non-transitory computer-readable medium of claim 9, wherein the instructions to compute the multi-modal conditional embedding further include instructions to:
concatenate a parametric embedding from the input embeddings associated with the completed parameter with a component embedding from the input embeddings associated with the assembled component;
project the parametric embedding and the component embedding into a multi-dimensional vector; and
add the parametric embedding and the component embedding to a text embedding from the input embeddings.

11. The non-transitory computer-readable medium of claim 9, wherein the instructions to control the foundational model further include instructions to:
modify a vector including the multi-modal conditional embedding using the controlnet; and
control the foundational model layer-by-layer using the vector.

12. The non-transitory computer-readable medium of claim 9, wherein the instructions to construct the completed parameter further include instructions to:
estimate the completed parameter using a diffusion model as one of the completion models from the incomplete parameter and the assembly graph, and the assembly graph identifies relationships between components of the object design.

13. A method comprising:
constructing a completed parameter and an assembled component using completion models from an assembly graph, an incomplete parameter, and a component image about an object design;
generating input embeddings using encoding models associated with the completed parameter, the assembled component, and a text description;
computing a multi-modal conditional embedding using multi-modal fusion from the input embeddings; and
controlling a foundational model using the multi-modal conditional embedding with a controlnet and outputting a generated object.

14. The method of claim 13, wherein computing the multi-modal conditional embedding further includes:
concatenating a parametric embedding from the input embeddings associated with the completed parameter with a component embedding from the input embeddings associated with the assembled component;
projecting the parametric embedding and the component embedding into a multi-dimensional vector; and
adding the parametric embedding and the component embedding to a text embedding from the input embeddings.

15. The method of claim 13, wherein controlling the foundational model further includes:
modifying a vector including the multi-modal conditional embedding using the controlnet; and
controlling the foundational model layer-by-layer using the vector.

16. The method of claim 13, wherein constructing the completed parameter further includes:
estimating the completed parameter using a diffusion model as one of the completion models from the incomplete parameter and the assembly graph, and the assembly graph identifies relationships between components of the object design.

17. The method of claim 16, wherein estimating the completed parameter further includes:
imputing parametric interdependencies from the assembly graph about the object design using a graph attention network (GAN), and the diffusion model is a tabular model.

18. The method of claim 13, wherein constructing the completed parameter and the assembled component further includes:
scaling and positioning a design image for the object design according to the assembly graph, and the assembly graph identifies relationships between the component image of the object design using edges and nodes and a size and a position of the component image are defined by the assembly graph; and
estimating the assembled component using a component assembler as one of the completion models from the component image and the assembly graph.

19. The method of claim 13 further comprising:
extracting a feature and a pattern from the assembled component using a component encoder, and the component encoder is a convolutional network; and
computing a component embedding using the component encoder from the feature and the pattern.

20. The method of claim 13, wherein generating the input embeddings further includes:
deriving semantic information and a design intent using a generative model from the text description, and the generative model is associated with one of a contrastive language-image pre-training (CLIP) model and a stable diffusion model.
